(19) United States
(12) Patent Application Publication
(10) Pub. No.: US 2018/0315731 A1
(43) Pub. Date: Nov. 1, 2018

(54) INKJET PRINTABLE MASK APPARATUS AND METHOD FOR SOLDER ON DIE TECHNOLOGY

(71) Applicant: INTEL CORPORATION, Santa Clara, CA (US)

(72) Inventors: Kosuke Hirota, Portland, OR (US); Mihir Oka, Chandler, AZ (US)

(73) Assignee: INTEL CORPORATION, Santa Clara, CA (US)

(21) Appl. No.: 15/772,503

(22) PCT Filed: Dec. 4, 2015
(86) PCT No.: PCT/US15/64120

§ 371 Date: Apr. 30, 2018

(51) Int. Cl. H01L 23/00; H01L 25/065; H01L 25/18

(52) U.S. Cl. CPC H01L 24/75; H01L 2225/06555; H01L 25/0657; H01L 25/18; H01L 2224/75155; H01L 2224/75189; H01L 2224/7525; H01L 2224/7501; H01L 2224/11515; H01L 2224/11318; H01L 2224/11462; H01L 2224/11849; H01L 2224/1181; H01L 2225/06513; H01L 2225/06582; H01L 2225/06541; H01L 24/11

(57) ABSTRACT

Described is an apparatus which comprises: a die with a first side; a plurality of metal bumps on the first side of the die; a plurality of solders disposed on the plurality of metal bumps; and a patterned printable resist disposed next to at least one of the solders of the plurality of solders. Described is a method which comprises: printing a photoresist ink onto a bumped wafer surface; thermally or Ultra-Violet curing the photoresist ink; and printing or electroplating solder(s) onto the bumped wafer surface. Described is a machine readable storage media having one or more instructions that when executed cause a machine to perform an operations according to the method described above.

### BACKGROUND

Current Solder-On-Die (SOD) process uses wet a chemistry process that involves developing and stripping the resist material using organic solvents. The chemicals used can be toxic and/or corrosive, e.g., strongly oxidizing acids. Use of these chemicals can also lead to environmental contamination. At assembly sites, the use of these strong solvents requires developing a new setup for solvent handling, recycling, and disposal. For example, solvents such as Tetranmethylammonium Hydroxide (TMAH or TMAOH) when used for stripping the resist material during the SOD process requires new sets of processes for solvent handling, recycling, and disposal. Such new sets of processes increases the cost of producing integrated circuit packages using SOD process.

### BRIEF DESCRIPTION OF THE DRAWINGS

The embodiments of the disclosure will be understood more fully from the detailed description given below and from the accompanying drawings of various embodiments of the disclosure, which, however, should not be taken to limit the disclosure to the specific embodiments, but are for explanation and understanding only.

FIGS. 1A-F illustrate cross-sections of a die during Solder-on-Die (SOD) process that uses a wet chemistry process.

FIGS. 2A-F illustrate cross-sections of a die during a SOD process that uses single nozzle inkjet for printing resist type material, according to some embodiments of the disclosure.

FIGS. 3A-F illustrate cross-sections of a die during a SOD process that uses multiple nozzle inkjet for printing resist type material, according to some embodiments of the disclosure.

FIG. 4 illustrates cross-sections of multiple dies coupled via solders formed using the inkjet printing resist process, according to some embodiments of the disclosure.

FIG. 5 illustrates a flowchart of an inkjet printing resist process as applied to the SOD process, according to some embodiments of the disclosure.

FIG. 6 illustrates a portion of the inkjet printer with machine-readable storage media having instructions that when executed cause the inkjet printer to print a resist type material, according to some embodiments of the disclosure.

FIG. 7 illustrates a smart device or a computer system or a SoC (System-on-Chip) which is packaged using the inkjet printing resist process as applied to the SOD process, according to some embodiments.

### DETAILED DESCRIPTION

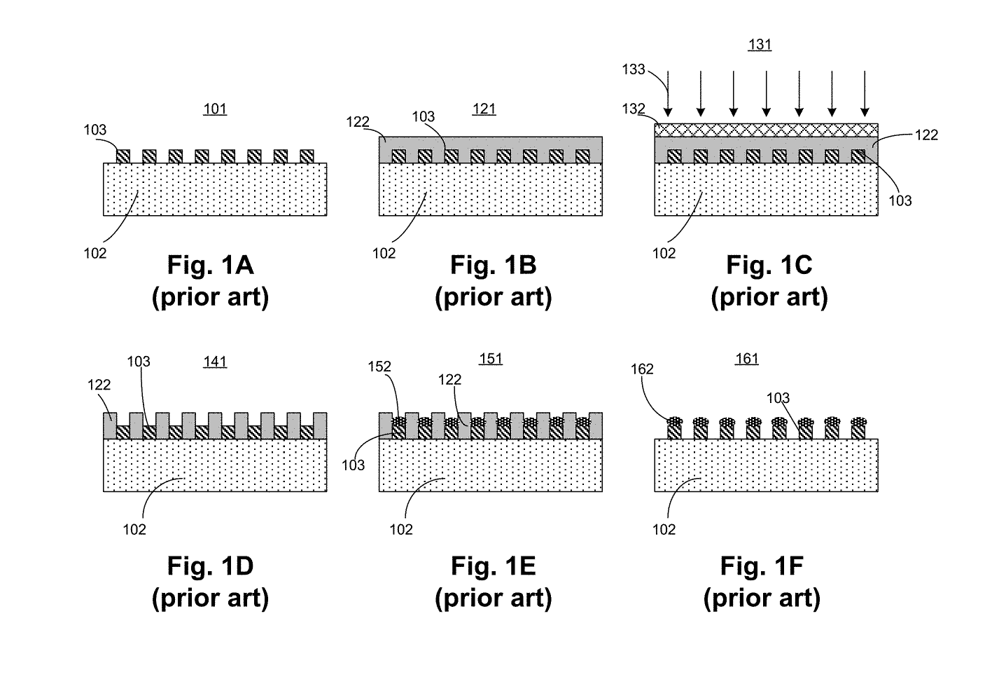

A process flow for Solder-On-Die (SOD) process on Silicon (Si) wafers is shown in FIGS. 1A-F. FIG. 1A illustrates cross-section 101 of a die 102 having metal bumps 103 (e.g., Cu bumps) disposed on the surface of die 102. Here, die 102 can be any die having active (e.g., transistors) and/or passive (e.g., resistors, capacitors, etc.) devices. FIG. 1B illustrates cross-section 121 with a coating of photoresist material 122 deposited on the bump side of die 102. Photoresist material 122 is a light-sensitive material used for patterned coating on a surface, for example. Photoresists are classified into two groups: positive photoresists and negative photoresists. A positive photoresist is a type of photoresist in which the portion of the photoresist that is exposed to light becomes soluble to the photoresist developer. In other words, the portion of the positive photoresist that is unexposed remains insoluble to the photoresist developer. A negative photoresist is an inverse of the positive photoresist. For example, a negative photoresist is a type of photoresist in which the portion of the photoresist that is exposed to light becomes insoluble to the photoresist developer. In other words, the unexposed portion of the negative photoresist is dissolved by the photoresist developer.

FIG. 1C illustrates cross-section 131 where a photoresist mask 132 is placed over the coating of photoresist 122. Photoresist mask 132 defines the pattern of the photoresist material (or pillars) for forming solder balls on metal bumps 103. Producing a photoresist mask 132 is an expensive process. Light or other active materials (collectively labeled as 133) are applied on photoresist mask 132. Photoresist material 122 are most commonly used at wavelengths in the ultraviolet spectrum or shorter. Photoresist material 122 can also be exposed by electron beams.

FIG. 1D illustrates cross-section 141 after light 133 is applied and the remainder structure is exposed to form a pattern of photoresist material 122. FIG. 1E illustrates cross-section 151 after solder material 152 is deposited above metal bumps 103 and between the towers or pillars of photoresist material 122. After reflow of the solder paste or material 152, solders 152 make firm contact with metal bumps 103 below them. FIG. 1G illustrates cross-section 161 after the photoresist material 122 is stripped leaving behind solders 162 (same as 152 but after reflow).

The process of masking photoresist 122, applying light 133, and manufacturing mask 132 are expensive set of processes. The processes of FIGS. 1A-F require photo-patterning which needs expensive irradiation tool and photo masks. An alternative laser ablation process is time consuming and expensive process especially with increased number of bumps.

Various embodiments described here use an inkjet printer and inkjet printable resist ink to provide a film-shaped pattern-resist for a Solder-on-Die (SOD) process. As opposed to the multi-step process of depositing and patterning photoresist in FIGS. 1B-D, various embodiments illustrate a one-step process to form a patterned resist between the bumps. The patterned resist can be stripped after the reflow process, in accordance with some embodiments. While various embodiments are described with reference to a patterned resist such as a photoresist, the embodiments are not limited to photoresist material. Other non-photoresist material can also be printed using the inkjet printer. For example, during wafer fabrication, non-photoresist material such as interlayer organic dielectric layers or organic passivation layers can be deposited using the inkjet printer according to the various embodiments.

There are many technical effects of the various embodiments. For example, the inkjet printing process of the various embodiments can, in a single step, directly print the resist material onto the bumped waver surface without expensive patterning tools/masks, in accordance with some embodiments. As such, the cost of mask preparation and handling is also avoided. The inkjet printing process of the various embodiments can also avoid wet chemicals for development, in accordance with some embodiments. The inkjet printing process of the various embodiments can also avoid the process of laser ablation to open via holes on bumps. In some embodiments, the process speed is determined by the thickness of the final resist film and may not depend on the pattern. As such, the throughput time does not increase with the process of the various embodiments even with numerous bumps. Other technical effects will be evident from the various embodiments and figures.

In the following description, numerous details are discussed to provide a more thorough explanation of embodiments of the present disclosure. It will be apparent, however, to one skilled in the art, that embodiments of the present disclosure may be practiced without these specific details. In other instances, well-known structures and devices are shown in block diagram form, rather than in detail, in order to avoid obscuring embodiments of the present disclosure.

Note that in the corresponding drawings of the embodiments, signals are represented with lines. Some lines may be thicker, to indicate more constituent signal paths, and/or have arrows at one or more ends, to indicate primary information flow direction. Such indications are not intended to be limiting. Rather, the lines are used in connection with one or more exemplary embodiments to facilitate easier understanding of a circuit or a logical unit. Any represented signal, as dictated by design needs or preferences, may actually comprise one or more signals that may travel in either direction and may be implemented with any suitable type of signal scheme.

Throughout the specification, and in the claims, the term “connected” means a direct connection, such as electrical, mechanical, or magnetic connection between the things that are connected, without any intermediary devices. The term “coupled” means a direct or indirect connection, such as a direct electrical, mechanical, or magnetic connection between the things that are connected or an indirect connection, through one or more passive or active intermediary devices. The term “circuit” or “module” may refer to one or more passive and/or active components that are arranged to cooperate with one another to provide a desired function. The term “signal” may refer to at least one current signal, voltage signal, magnetic signal, or data/clock signal. The meaning of “a,” “an,” and “the” include plural references. The meaning of “in” includes “in” and “on.”

The term “scaling” generally refers to converting a design (schematic and layout) from one process technology to another process technology and subsequently being reduced in layout area. The term “scaling” generally also refers to downsizing layout and devices within the same technology node. The term “scaling” may also refer to adjusting (e.g., slowing down or speeding up—i.e. scaling down, or scaling up respectively) of a signal frequency relative to another parameter, for example, power supply level. The terms “substantially,” “close,” “approximately,” “near,” and “about,” generally refer to being within +/−10% of a target value.

Unless otherwise specified the use of the ordinal adjectives “first,” “second,” and “third,” etc., to describe a common object, merely indicate that different instances of like objects are being referred to, and are not intended to imply that the objects so described must be in a given sequence, either temporally, spatially, in ranking or in any other manner.

For the purposes of the present disclosure, phrases “A and/or B” and “A or B” mean (A), (B), or (A and B). For the purposes of the present disclosure, the phrase “A, B, and/or C” means (A), (B), (C), (A and B), (A and C), (B and C), or (A, B and C). The terms “left,” “right,” “front,” “back,” “top,” “bottom,” “over,” “under,” and the like in the description and in the claims, if any, are used for descriptive purposes and not necessarily for describing permanent relative positions.

For purposes of the embodiments, the transistors in various circuits and logic blocks described here are metal oxide semiconductor (MOS) transistors or their derivatives, where the MOS transistors include drain, source, gate, and bulk terminals. The transistors and/or the MOS transistor derivatives also include Tri-Gate and FinFET transistors, Gate All Around Cylindrical Transistors, Tunneling FET (TFET), Square Wire, or Rectangular Ribbon Transistors, ferroelectric FET (FeFETs), or other devices implementing transistor functionality like carbon nanotubes or spintronic devices. MOSFET symmetrical source and drain terminals i.e., are identical terminals and are interchangeably used here. A TFET device, on the other hand, has asymmetric Source and Drain terminals. Those skilled in the art will appreciate that other transistors, for example, Bi-polar junction transistors—BJT PNP/NPN, BiCMOS, CMOS, etc., may be used without departing from the scope of the disclosure.

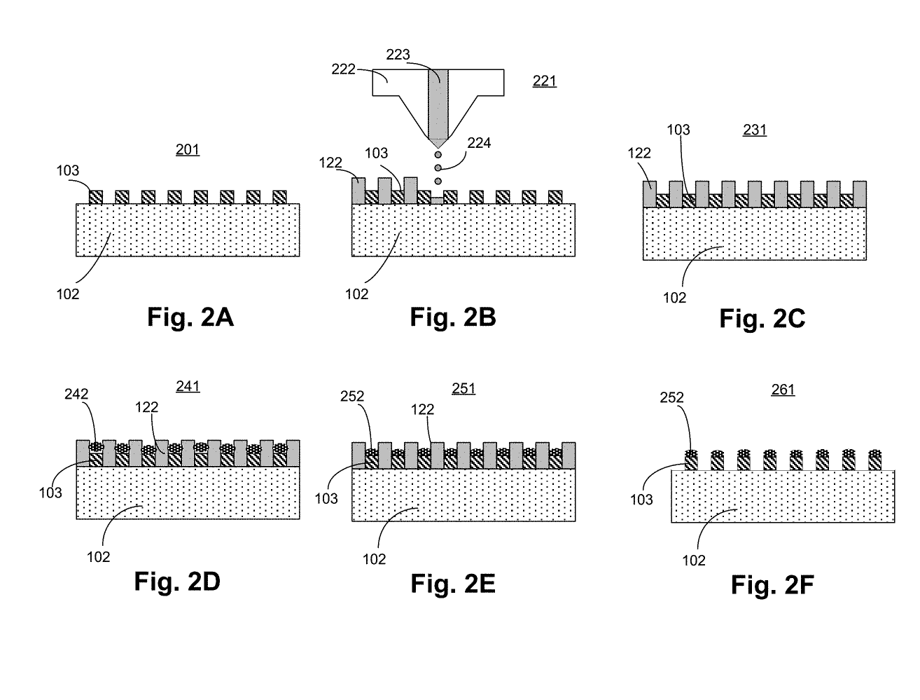

FIGS. 2A-F illustrate cross-sections 201, 221, 231, 241, 251, and 261, of a die during a SOD process that uses a single nozzle inkjet for printing photoresist, according to some embodiments of the disclosure. It is pointed out that those elements of FIGS. 2A-F having the same reference numbers (or names) as the elements of any other figure can operate or function in any manner similar to that described, but are not limited to such.

With reference to FIG. 2A, cross-section 201 is the same as cross-section 101 and includes die 102 (e.g., a silicon die) and metal bumps 103 (e.g., Cu bumps). These metal bumps 103 are then connected to a package. In some embodiments, a layer (not shown) is deposited around the metal bumps 103. In some embodiments, this layer is used to make sure that a flat surface is provided for a photo-resist to be laminated. In some embodiments, the layer surrounds the at least one of the metal bumps 103. In some embodiments, the layer is removal material. In some embodiments, the removal material is a sacrificial resist. In some embodiments, the layer is a permanent material. In some embodiments, the permanent material is a wafer level under-fill. In some embodiments, the layer is deposited on a side of the die such that it is to provide a flat surface for the printable resist.

FIG. 2B illustrates the process of printing resist material 223 on die 102, in accordance with some embodiments. So as not to obscure various embodiments, various intermediate processing steps are not shown. For example, a sacrificial layer in between bumps is not shown but may be used to make sure that a flat surface is provided for the photo-resist to be laminated.

In some embodiments, inkjet printer 222 is provided which selectively drops resist material 223 as drops 224 on die 102. In some embodiments, drops 224 form pillars or towers of resist 122 between metal bumps 103. In some embodiments, inkjet printer 222 is a single nozzle printer which moves along the surface of die 102 to drop resist material 223 between metal bumps 103.

In some embodiments, inkjet printer 222 is operable to move along ‘x’ and ‘y’ axis by a machine so that inkjet printer 222 can drop resist material 223 between metal bumps 103 according to a pattern. In some embodiments, a pattern is fed into inkjet printer 222 through a software. The pattern may indicate where inkjet printer 222 should drop resist material 223 to form photoresist pillars 122. As such, with one step, inkjet printer 222 is operable to provide resist material 223 and pattern pillars 122 of resist material 223 between metal bumps 103 without the need for a mask and light along with its corresponding source to pattern the resist. Accordingly, the process of fabricating the solders on die is simplified resulting in time and cost savings.

While the various embodiments are illustrated with reference to a photoresist material being injected by an inkjet printer, other materials that can survive the process of plating and have thermal and chemical resistance for application of solders on the metal bumps, can be used as material injected by inkjet printer 222. For example, in some embodiments, the resist material is a solder resist material. Application of solder resist on a substrate is a filled system (e.g., it contains high percentage of fillers). In some embodiments, any resist material which can be dropped down using inkjet printing technology can be used as resist material 223.

For example, resist material 223 is a photoresist material which is an ink containing polymer material. In another example, resist material 223 is a thermally curable polymer, heat resistant resin, or Ultraviolet light (UV) curable polymer. In some embodiments, resist material 223 is polyimide. Other examples of resist materials include: heat resistant material, phenolic resin, polyamide, poly (amideimide), polybenzoxazine, polybenzoxazole, polybenzimidazole, etc.

FIG. 2C illustrates cross-section 231 after curing of resist material 223/122, according to some embodiments of the disclosure. The process of curing of photoresist material 122 is any known scuring process. For example, heating and/or ultra-violet (UV) exposure of die 102 can cure photoresist material 223/122.

FIG. 2D illustrates cross-section 241 after solder material 242 (same material as 152) is pasted on metal bumps 103 between pillars 122 of photoresist material 122. A variety of materials can be used for solder material 242. For example, silver, antimony, copper, tin, bismuth, indium, zinc, and their alloys can be used as solder material 242. Generally, lead-free solder materials are preferred. Other examples of solder material 242 include: Cu₄Sn, Cu₆Sn₅, Cu₃Sn, Cu₃Sn₈ Cu₃In, Cu₉In₄, Ni₃Sn, Ni₃Sn₂, Ni₃Sn₄, NiSn₃, Ni₃In, NiIn, Ni₂In₃, Ni₃In₇, FeSn, FeSn₂, In₃Sn, InSn₄, In₃Pb, SbSn, BiPb₃, Ag₆Sn, Ag₃Sn, Ag₃In, AgIn₂ Au₅Sn, AuSn AuSn₂, AuSn₄, Au₂Pb, AuPb₂, AuIn, AuIn₂, Pd₃Sn, Pd₂Sn, Pd₃Sn₂, PdSn, PdSn₂, PdSn₄ Pd₃In, Pd₂In, PdIn, Pd₂In₃, Pt₃Sn, Pt₂Sn, PtSn, Pt₂Sn₃, PtSn₂, PtSn₄, Pt₃Pb, PtPb, PtPb₄, Pt₂n₃, PtIn₂, Pt₃In₇, etc. In some embodiments, solder material 242 is deposited using another inkjet printer or another nozzle of the same inkjet printer 222.

FIG. 2E illustrates cross-section 251 after reflow soldering. Reflow soldering is a process in which solder paste 242 is used to attach to metal bumps 103, after which the entire assembly is subjected to controlled heat, which melts solder paste 242, permanently connecting metal bumps 103. One purpose of the reflow process is to melt solder paste 242 and heat the adjoining surfaces (e.g., photoresist pillars 122) without overheating and damaging die 102. A reflow soldering process may have sequential stages including: preheat, thermal soak, reflow, and cooling. After reflow, solder paste 242 becomes solder ball 252 (same material as solder ball 152) which is tightly attached to metal bumps 103.

FIG. 2F illustrates cross-section 261 after the photoresist pillars 122 (or patterned photoresist) are stripped out leaving behind soldered bumps or balls 252 for coupling to a package. In some embodiments, chemical etching process is used to strip patterned photoresist 122. For example, patterned photoresist 122 is stripped using an alkaline solution. Any suitable material that can cleanly strip patterned photoresist 122 without causing any damage to die 102, metal bumps 103, and solder balls 252 can be used for stripping patterned photoresist 122. For example, solvent based striping agents such as DMSO (Dimethyl Sulfoxide) based, TMAH (Tetramethylammonium Hydroxide) based, NMP (N-Methyl-2-Pyrrolidone) based, DMSO plus NMP based, solvent based strippers containing ketones, for instance, cyclohexanone, aqueous based alkaline strippers, etc. may be used for cleanly stripping patterned photoresist 122.

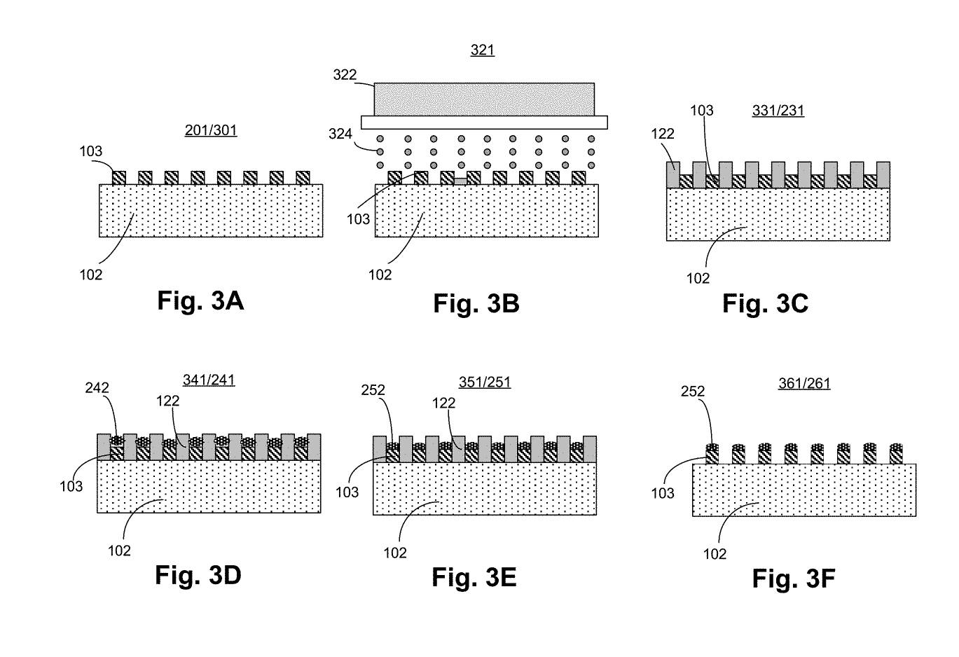

FIGS. 3A-F illustrate cross-sections 301/201, 321, 331/231, 341/241, 351/251, and 361/261 of a die during SOD process that uses multiple nozzle inkjet for printing photoresist, according to some embodiments of the disclosure. It is pointed out that those elements of FIGS. 3A-F having the same reference numbers (or names) as the elements of any other figure can operate or function in any manner similar to that described, but are not limited to such. Except for cross-section 321, other cross-sections in FIGS. 3A-F are substantially the same as those described with reference to FIGS. 2A-F. Here, instead of single nozzle inkjet printer 222, a multiple nozzle inkjet printer 322 is used.

In some embodiments, multiple nozzle inkjet printer 322 is operable to selectively drop photoresist material 324 between metal bumps 103 for the entire die or for part of the die. For example, multiple nozzle inkjet printer 322 is operable to selectively drop photoresist material 324 per row or column of die 102. In some embodiments, surface area of multiple nozzle inkjet printer 322 is sufficient enough to cover the entire surface of die 102. As such, patterns of photoresist pillars 122 are formed in one step for the entire die 102. Accordingly, process described with reference to FIGS. 3A-F is faster than the process described with reference to FIGS. 2A-F, in accordance with some embodiments.

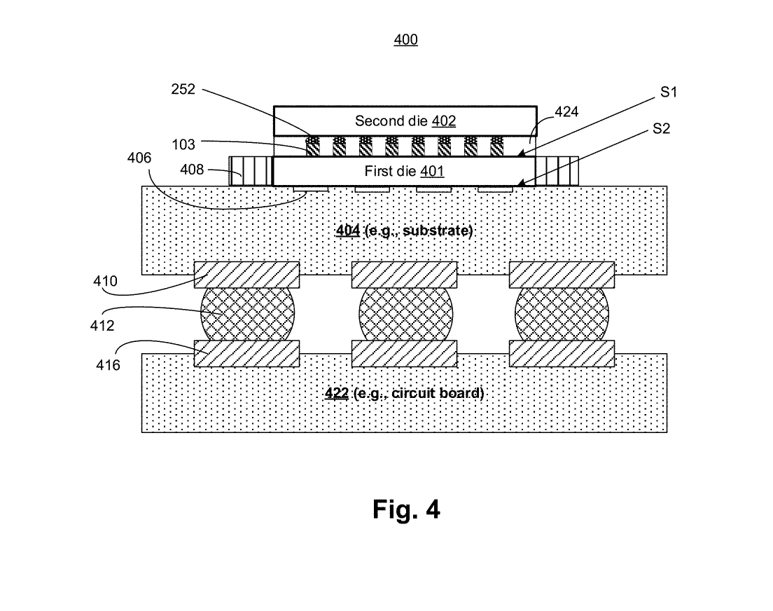

FIG. 4 illustrates cross-section 400 of multiple dies coupled via solders formed using the inkjet printing photoresist process, according to some embodiments of the disclosure. It is pointed out that those elements of FIG. 4 having the same reference numbers (or names) as the elements of any other figure can operate or function in any manner similar to that described, but are not limited to such.

In some embodiments, cross-sectional view 400 is of an integrated circuit (IC) package assembly, in accordance with various embodiments. In some embodiments, IC package assembly may include First die 401, package substrate 404, and circuit board 422. IC package assembly of cross-sectional view 400 is one example of a stacked die configuration in which First die 401 is coupled to package substrate 404, and Second die 402 is coupled with First die 401, in accordance with some embodiments.

In some embodiments, First die 401 may have a first side S1 and a second side S2 opposite to the first side S1. In some embodiments, first side S1 may be the side of the die commonly referred to as the “inactive” or “back” side of the die. In some embodiments, second side S2 may include one or more transistors, and may be the side of the die commonly referred to as the “active” or “front” side of the die. In some embodiments, Second side S2 of First die 401 may include one or more electrical routing features 406. In some embodiments, Second die 402 may include an “active” or “front” side with one or more electrical routing features 406. In some embodiments, electrical routing features 406 may be bond pads (e.g., formed from a combination of metal bumps 103 and solder balls 252).

In some embodiments, Second die 402 may be coupled to First die 401 in a front-to-back configuration (e.g., the “front” or “active” side of Second die 402 is coupled to the “back” or “inactive” side S1 of First die 401). In some embodiments, dies may be coupled with one another in a front-to-front, back-to-back, or side-to-side arrangement. In some embodiments, one or more additional dies may be coupled with First die 401, Second die 402, and/or with package substrate 404. Other embodiments may lack Second die 402. In some embodiments, First die 401 may include one or more through-silicon vias (TSVs).

In some embodiments, Second die 402 is coupled to First die 401 by die interconnects formed from combination of bumps 103 and solder balls 252. In some embodiments, the solder balls 252 are formed using the process described with reference to FIGS. 2-3. Referring back to FIG. 4, in some embodiments, inter-die interconnects may be solder bumps, copper pillars, or other electrically conductive features. In some embodiments, an interface layer 424 may be provided between First die 401 and Second die 402. In some embodiments, interface layer 424 may be, or may include, a layer of under-fill, adhesive, dielectric, or other material. In some embodiments, interface layer 424 may serve various functions, such as providing mechanical strength, conductivity, heat dissipation, or adhesion.

In some embodiments, First die 401 and Second die 402 may be single dies. In other embodiments, First die 401 and/or Second die 402 may include two or more dies. For example, in some embodiments First die 401 and/or Second die 402 may be a wafer (or portion of a wager) having two or more dies formed on it. In some embodiments, First die 401 and/or Second die 402 includes two or more dies embedded in an encapsulant. In some embodiments, the two or more dies are arranged side-by-side, vertically stacked, or positioned in any other suitable arrangement. In some embodiments, the IC package assembly may include, for example, combinations of flip-chip and wire-bonding techniques, interposers, multi-chip package configurations including system-on-chip (SoC) and/or package-on-package (PoP) configurations to route electrical signals.

In some embodiments, First die 401 and/or Second die 402 may be a primary logic die. In some embodiments, First die 401 and/or Second die 402 may be configured to function as memory, an application specific circuit (ASIC), a processor, or some combination of such functions. For example, First die 401 may include a processor and Second die 402 may include memory. In some embodiments, one or both of First die 401 and Second die 402 may be embedded in encapsulant 408. In some embodiments, encapsulant 408 can be any suitable material, such as epoxy-based build-up substrate, other dielectric/organic materials, resins, epoxies, polymer adhesives, silicones, acrylics, polyimides, cyanate esters, thermoplastics, and/or thermosets.

In some embodiments, First die 401 may be coupled to package substrate 404. In some embodiments, package substrate 404 may be a coreless substrate. For example, package substrate 404 may be a bumpless build-up layer (BBUL) assembly that includes a plurality of “bumpless” build-up layers. Here, the term “bumpless build-up layers” generally refers to layers of substrate and components embedded therein without the use of solder or other attaching means that may be considered “bumps.” However, the various embodiments are not limited to BBUL type connections between die and substrate, but can be used for any suitable flip chip substrates.

In some embodiments, the one or more build-up layers may have material properties that may be altered and/or optimized for reliability, warpage reduction, etc. In some embodiments, package substrate 404 may be composed of a polymer, ceramic, glass, or semiconductor material. In some embodiments, package substrate 404 may be a conventional cored substrate and/or an interposer.

In some embodiments, circuit board 422 may be a Printed Circuit Board (PCB) composed of an electrically insulative material such as an epoxy laminate. For example, circuit board 422 may include electrically insulating layers composed of materials such as, phenolic cotton paper materials (e.g., FR-1), cotton paper and epoxy materials (e.g., FR-3), woven glass materials that are laminated together using an epoxy resin (FR-4), glass/paper with epoxy resin (e.g., CEM-1), glass composite with epoxy resin, woven glass cloth with polytetrafluoroethylene (e.g., PTFE CCL), or other polytetrafluoroethylene-based prepreg material.

Structures such as traces, trenches, and vias (which are not shown here) may be formed through the electrically insulating layers to route the electrical signals of First die 401 through the circuit board 422. Circuit board 422 may be composed of other suitable materials in other embodiments. In some embodiments, circuit board 422 may include other electrical devices coupled to the circuit board that are configured to route electrical signals to or from First die 401 through circuit board 422. In some embodiments, circuit board 422 may be a motherboard.

In some embodiments, a first side of package substrate 404 is coupled to second surface S2 and/or electrical routing features 406 of First die 401. In some embodiments, a second opposite side of package substrate 404 is coupled to circuit board 422 by package interconnects 412. In some embodiments, package interconnects 412, like solder balls 252, are formed using the process described with reference to FIGS. 2-3. In some embodiments, package interconnects 412 may couple electrical routing features 410 disposed on the second side of package substrate 404 to corresponding electrical routing features 416 on circuit board 422.

In some embodiments, package substrate 404 may have electrical routing features formed therein to route electrical signals between First die 401 (and/or the Second die 402) and circuit board 422 and/or other electrical components external to the IC package assembly. In some embodiments, package interconnects 412 and die interconnects 406 include any of a wide variety of suitable structures and/or materials including, for example, bumps, pillars or balls formed using metals, alloys, solderable material, or their combinations. In some embodiments, electrical routing features 410 may be arranged in a ball grid array (“BGA”) or other configuration.

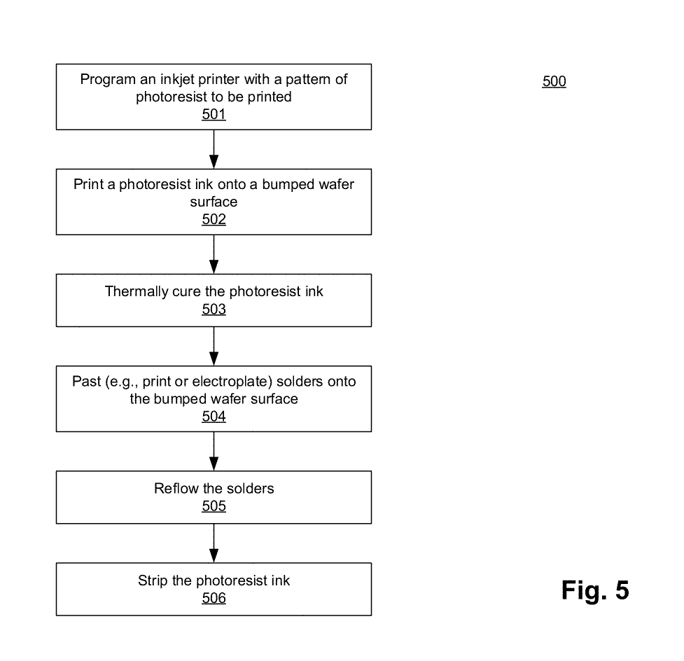

FIG. 5 illustrates flowchart 500 of an inkjet printing photoresist process as applied to the SOD process, according to some embodiments of the disclosure. It is pointed out that those elements of FIG. 5 having the same reference numbers (or names) as the elements of any other figure can operate or function in any manner similar to that described, but are not limited to such.

Although the blocks in the flowchart with reference to FIG. 5 are shown in a particular order, the order of the actions can be modified. Thus, the illustrated embodiments can be performed in a different order, and some actions/blocks may be performed in parallel. Some of the blocks and/or operations listed in FIG. 5 are optional in accordance with certain embodiments. The numbering of the blocks presented is for the sake of clarity and is not intended to prescribe an order of operations in which the various blocks must occur. Additionally, operations from the various flows may be utilized in a variety of combinations.

At block 501, inkjet printer 222/322 is programmed with a pattern of the photoresist pillars 122 to be patterned on die 102. Programming the pattern is much more cost effective than fabricating and applying a mask for making photoresist pillars 122. In some embodiments, any known programming language can be used for programming inkjet printer 222/322.

At block 502, inkjet printer 222/322 prints photoresist ink 223 on die 102 as described with reference to FIGS. 2-3. At block 503, the photoresist ink which is now in the form of pillars 122 on die 102 is thermally cured. At block 504, solders 242 are pasted on to bumps 103 (e.g., on to the bumped waver surface). For example, solders are printed or electroplated onto the bumped wafer surface. At block 505, the reflow process is performed and solder paste 242 are tightly attached to metal bumps 103 as solder balls 252. At block 506, photoresist pillars 122 are stripped leaving behind solder balls 252 on top of metal bumps 103.

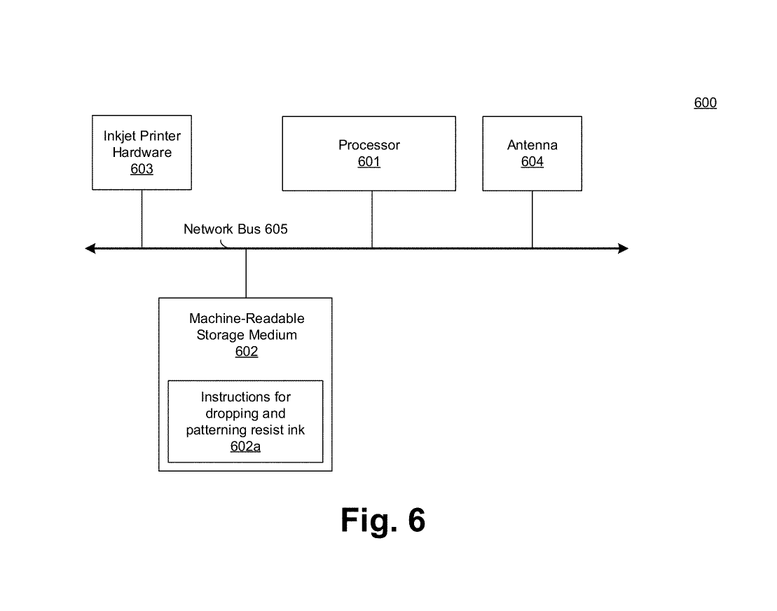

FIG. 6 illustrates a portion 600 of the inkjet printer with machine-readable storage media having instructions that when executed cause the inkjet printer to print a photoresist material, according to some embodiments of the disclosure. It is pointed out that those elements of FIG. 6 having the same reference numbers (or names) as the elements of any other figure can operate or function in any manner similar to that described, but are not limited to such.

In some embodiments, portion 600 comprises Processor 601 (e.g., a Digital Signal Processor (DSP), an Application Specific Integrated Circuit (ASCI), a general purpose Central Processing Unit (CPU), or a low power logic executing flowchart 500, etc.), Machine-Readable Storage media 602 (also referred to as tangible machine readable medium), Inkjet Printer Hardware 503 (e.g., printer nozzle and hardware that can execute instructions) Antenna 604, and Network Bus 605.

Any suitable protocol may be used to implement Network Bus 605. In some embodiments, Machine-Readable Storage Media 602 includes Instructions 602a (also referred to as the program software code/instructions) for calculating or measuring distance and relative orientation of a device with reference to another device as described with reference to various embodiments and flowchart.

Program software code/instructions 602a associated with flowchart 500 and executed to implement embodiments of the disclosed subject matter may be implemented as part of an operating system or a specific application, component, program, object, module, routine, or other sequence of instructions or organization of sequences of instructions referred to as “program software code/instructions,” “operating system program software code/instructions,” “application program software code/instructions,” or simply “software” or firmware embedded in processor. In some embodiments, the program software code/instructions associated with flowchart 600 are executed by inkjet printer 600.

Referring back to FIG. 6, in some embodiments, the program software code/instructions 602a associated with flowchart 500 are stored in a computer executable storage medium 602 and executed by Processor 601. Here, computer executable storage medium 602 is a tangible machine readable medium that can be used to store program software code/instructions and data that, when executed by a computing device, causes one or more processors (e.g., Processor 601) to perform a method(s) as may be recited in one or more accompanying claims directed to the disclosed subject matter.

The tangible machine readable medium 602 may include storage of the executable software program code/instructions 602a and data in various tangible locations, including for example ROM, volatile RAM, non-volatile memory and/or cache and/or other tangible memory as referenced in the present application. Portions of this program software code/instructions 602a and/or data may be stored in any one of these storage and memory devices. Further, the program software code/instructions can be obtained from other storage, including, e.g., through centralized servers or peer to peer networks and the like, including the Internet. Different portions of the software program code/instructions and data can be obtained at different times and in different communication sessions or in the same communication session.

The software program code/instructions 602a (associated with flowchart 500 and other embodiments) and data can be obtained in their entirety prior to the execution of a respective software program or application by the computing device. Alternatively, portions of the software program code/instructions 602a and data can be obtained dynamically, e.g., just in time, when needed for execution. Alternatively, some combination of these ways of obtaining the software program code/instructions 602a and data may occur, e.g., for different applications, components, programs, objects, modules, routines or other sequences of instructions or organization of sequences of instructions, by way of example. Thus, it is not required that the data and instructions be on a tangible machine readable medium in entirety at a particular instance of time.

Examples of tangible computer-readable media 602 include but are not limited to recordable and non-recordable type media such as volatile and non-volatile memory devices, read only memory (ROM), random access memory (RAM), flash memory devices, floppy and other removable disks, magnetic storage media, optical storage media (e.g., Compact Disk Read-Only Memory (CD ROMS), Digital Versatile Disks (DVDs), etc.), among others. The software program code/instructions may be temporarily stored in digital tangible communication links while implementing electrical, optical, acoustical or other forms of propagating signals, such as carrier waves, infrared signals, digital signals, etc. through such tangible communication links.

In general, tangible machine readable medium 602 includes any tangible mechanism that provides (i.e., stores and/or transmits in digital form, e.g., data packets) information in a form accessible by a machine (i.e., a computing device), which may be included, e.g., in a communication device, a computing device, a network device, a personal digital assistant, a manufacturing tool, a mobile communication device, whether or not able to download and run applications and subsidized applications from the communication network, such as the Internet, e.g., an iPhone®, Galaxy®, Blackberry® Droid®, or the like, or any other device including a computing device. In one embodiment, processor-based system is in a form of or included within a PDA (personal digital assistant), a cellular phone, a notebook computer, a tablet, a game console, a set top box, an embedded system, a TV (television), a personal desktop computer, etc. Alternatively, the traditional communication applications and subsidized application(s) may be used in some embodiments of the disclosed subject matter.

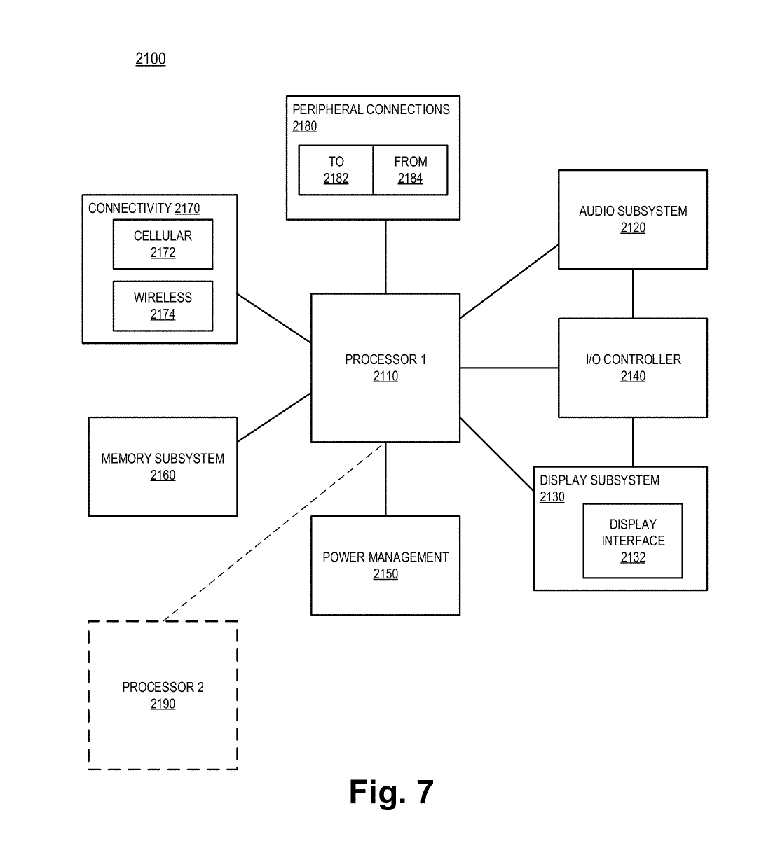

FIG. 7 illustrates a smart device or a computer system or a SoC 2100 which is packaged using the inkjet printing resist process as applied to the SOD process, according to some embodiments. It is pointed out that those elements of FIG. 7 having the same reference numbers (or names) as the elements of any other figure can operate or function in any manner similar to that described, but are not limited to such.

FIG. 7 illustrates a block diagram of an embodiment of a mobile device in which flat surface interface connectors could be used. In some embodiments, computing device 2100 represents a mobile computing device, such as a computing tablet, a mobile phone or smart-phone, a wireless-enabled e-reader, or other wireless mobile device. It will be understood that certain components are shown generally, and not all components of such a device are shown in computing device 2100.

In some embodiments, computing device 2100 includes a first processor 2110 (e.g., First die 401). The various embodiments of the present disclosure may also comprise a network interface within 2170 such as a wireless interface so that a system embodiment may be incorporated into a wireless device, for example, cell phone or personal digital assistant.

In one embodiment, processor 2110 (and/or processor 2190, e.g., Second die 402) can include one or more physical devices, such as microprocessors, application processors, microcontrollers, programmable logic devices, or other processing means. The processing operations performed by processor 2110 include the execution of an operating platform or operating system on which applications and/or device functions are executed. The processing operations include operations related to I/O (input/output) with a human user or with other devices, operations related to power management, and/or operations related to connecting the computing device 2100 to another device. The processing operations may also include operations related to audio I/O and/or display I/O.

In one embodiment, computing device 2100 includes audio subsystem 2120, which represents hardware (e.g., audio hardware and audio circuits) and software (e.g., drivers, codecs) components associated with providing audio functions to the computing device. Audio functions can include speaker and/or headphone output, as well as microphone input. Devices for such functions can be integrated into computing device 2100, or connected to the computing device 2100. In one embodiment, a user interacts with the computing device 2100 by providing audio commands that are received and processed by processor 2110.

Display subsystem 2130 represents hardware (e.g., display devices) and software (e.g., drivers) components that provide a visual and/or tactile display for a user to interact with the computing device 2100. Display subsystem 2130 includes display interface 2132, which includes the particular screen or hardware device used to provide a display to a user. In one embodiment, display interface 2132 includes logic separate from processor 2110 to perform at least some processing related to the display. In one embodiment, display subsystem 2130 includes a touch screen (or touch pad) device that provides both output and input to a user.

I/O controller 2140 represents hardware devices and software components related to interaction with a user. I/O controller 2140 is operable to manage hardware that is part of audio subsystem 2120 and/or display subsystem 2130. Additionally, I/O controller 2140 illustrates a connection point for additional devices that connect to computing device 2100 through which a user might interact with the system. For example, devices that can be attached to the computing device 2100 might include microphone devices, speaker or stereo systems, video systems or other display devices, keyboard or keypad devices, or other I/O devices for use with specific applications such as card readers or other devices.

As mentioned above, I/O controller 2140 can interact with audio subsystem 2120 and/or display subsystem 2130. For example, input through a microphone or other audio device can provide input or commands for one or more applications or functions of the computing device 2100. Additionally, audio output can be provided instead of, or in addition to display output. In another example, if display subsystem 2130 includes a touch screen, the display device also acts as an input device, which can be at least partially managed by I/O controller 2140. There can also be additional buttons or switches on the computing device 2100 to provide I/O functions managed by I/O controller 2140.

In one embodiment, I/O controller 2140 manages devices such as accelerometers, cameras, light sensors or other environmental sensors, or other hardware that can be included in the computing device 2100. The input can be part of direct user interaction, as well as providing environmental input to the system to influence its operations (such as filtering for noise, adjusting displays for brightness detection, applying a flash for a camera, or other features).

In one embodiment, computing device 2100 includes power management 2150 that manages battery power usage, charging of the battery, and features related to power saving operation. Memory subsystem 2160 includes memory devices for storing information in computing device 2100. Memory can include nonvolatile (state does not change if power to the memory device is interrupted) and/or volatile (state is indeterminate if power to the memory device is interrupted) memory devices. Memory subsystem 2160 can store application data, user data, music, photos, documents, or other data, as well as system data (whether long-term or temporary) related to the execution of the applications and functions of the computing device 2100.

Elements of embodiments are also provided as a machine-readable medium (e.g., memory 2160) for storing the computer-executable instructions. The machine-readable medium (e.g., memory 2160) may include, but is not limited to, flash memory, optical disks, CD-ROMs, DVD ROMs, RAMs, EPROMs, EEPROMs, magnetic or optical cards, phase change memory (PCM), or other types of machine-readable media suitable for storing electronic or computer-executable instructions. For example, embodiments of the disclosure may be downloaded as a computer program (e.g., BIOS) which may be transferred from a remote computer (e.g., a server) to a requesting computer (e.g., a client) by way of data signals via a communication link (e.g., a modem or network connection).

Connectivity 2170 includes hardware devices (e.g., wireless and/or wired connectors and communication hardware) and software components (e.g., drivers, protocol stacks) to enable the computing device 2100 to communicate with external devices. The computing device 2100 could be separate devices, such as other computing devices, wireless access points or base stations, as well as peripherals such as headsets, printers, or other devices.

Connectivity 2170 can include multiple different types of connectivity. To generalize, the computing device 2100 is illustrated with cellular connectivity 2172 and wireless connectivity 2174. Cellular connectivity 2172 refers generally to cellular network connectivity provided by wireless carriers, such as provided via GSM (global system for mobile communications) or variations or derivatives, CDMA (code division multiple access) or variations or derivatives, TDM (time division multiplexing) or variations or derivatives, or other cellular service standards. Wireless connectivity (or wireless interface) 2174 refers to wireless connectivity that is not cellular, and can include personal area networks (such as Bluetooth, Near Field, etc.), local area networks (such as Wi-Fi), and/or wide area networks (such as WiMax), or other wireless communication.

Peripheral connections 2180 include hardware interfaces and connectors, as well as software components (e.g., drivers, protocol stacks) to make peripheral connections. It will be understood that the computing device 2100 could both be a peripheral device (“to” 2182) to other computing devices, as well as have peripheral devices (“from” 2184) connected to it. The computing device 2100 commonly has a “docking” connector to connect to other computing devices for purposes such as managing (e.g., downloading and/or uploading, changing, synchronizing) content on computing device 2100. Additionally, a docking connector can allow computing device 2100 to connect to certain peripherals that allow the computing device 2100 to control content output, for example, to audiovisual or other systems.

In addition to a proprietary docking connector or other proprietary connection hardware, the computing device 2100 can make peripheral connections 1680 via common or standards-based connectors. Common types can include a Universal Serial Bus (USB) connector (which can include any of a number of different hardware interfaces), DisplayPort including MiniDisplayPort (MDP), High Definition Multimedia Interface (HDMI), Firewire, or other types.

Reference in the specification to “an embodiment,” “one embodiment,” “some embodiments,” or “other embodiments” means that a particular feature, structure, or characteristic described in connection with the embodiments is included in at least some embodiments, but not necessarily all embodiments. The various appearances of “an embodiment,” “one embodiment,” or “some embodiments” are not necessarily all referring to the same embodiments. If the specification states a component, feature, structure, or characteristic “may,” “might,” or “could” be included, that particular component, feature, structure, or characteristic is not required to be included. If the specification or claim refers to “a” or “an” element, that does not mean there is only one of the elements. If the specification or claims refer to “an additional” element, that does not preclude there being more than one of the additional element.

Furthermore, the particular features, structures, functions, or characteristics may be combined in any suitable manner in one or more embodiments. For example, a first embodiment may be combined with a second embodiment anywhere the particular features, structures, functions, or characteristics associated with the two embodiments are not mutually exclusive

While the disclosure has been described in conjunction with specific embodiments thereof, many alternatives, modifications and variations of such embodiments will be apparent to those of ordinary skill in the art in light of the foregoing description. The embodiments of the disclosure are intended to embrace all such alternatives, modifications, and variations as to fall within the broad scope of the appended claims.

In addition, well known power/ground connections to integrated circuit (IC) chips and other components may or may not be shown within the presented figures, for simplicity of illustration and discussion, and so as not to obscure the disclosure. Further, arrangements may be shown in block diagram form in order to avoid obscuring the disclosure, and also in view of the fact that specifics with respect to implementation of such block diagram arrangements are highly dependent upon the platform within which the present disclosure is to be implemented (i.e., such specifics should be well within purview of one skilled in the art). Where specific details (e.g., circuits) are set forth in order to describe example embodiments of the disclosure, it should be apparent to one skilled in the art that the disclosure can be practiced without, or with variation of, these specific details. The description is thus to be regarded as illustrative instead of limiting.

The following examples pertain to further embodiments. Specifics in the examples may be used anywhere in one or more embodiments. All optional features of the apparatus described herein may also be implemented with respect to a method or process.

For example, an apparatus is provided which comprises: a die with a first side; a plurality of metal bumps on the first side of the die; a printable resist disposed next to at least one of the metal bumps on the first side of the die; and a plurality of solders disposed on the plurality of metal bumps. In some embodiments, the printable resist is an ink injected from an inkjet printer, wherein the ink is at least one of: polyimide; solder resist material; polymer material; thermally curable polymer; heat resistant resin; or Ultraviolet light (UV) curable polymer. In some embodiments, the inkjet printer is operable via software.

In some embodiments, the inject printer is operable to inject the printable resist from a single nozzle of the inject printer in a preprogrammed pattern. In some embodiments, the inject printer is operable to inject the printable resist from multiple nozzles of the inject printer. In some embodiments, the die has a second side opposite to the first side, wherein the second side includes one or more transistors.

In another example, a system is provided which comprises: a memory; a processor coupled to the memory; a package encasing the processor, the package including an apparatus according to the apparatus described above; and a wireless interface for allowing the processor to communicate with another device.

In another example, an apparatus is provided which comprises: a die with a first side; a plurality of metal bumps on the first side of the die; and a plurality of solders disposed on the plurality of metal bumps, wherein the plurality of metal bumps are positioned according to a patterned printable resist. In some embodiments, the patterned printable resist is formed using an inkjet printer. In some embodiments, the patterned printable resist is an ink based resist. In some embodiments, the inkjet printer is operable to dispose one of: polyimide ink, solder resist material, polymer material ink, thermally curable polymer ink; or heat resistant resin ink over next to at least one of the metal bumps of the plurality of metal bumps. In some embodiments, the inkjet printer is operable via firmware. In some embodiments, the die has a second side opposite to the first side, wherein the second side includes one or more transistors.

In another example, a system is provided which comprises: a memory; a processor coupled to the memory; a package encasing the processor, the package including an apparatus according to the apparatus described above; and a wireless interface for allowing the processor to communicate with another device.

In another example, a method is provided which comprises: printing a resist ink onto a bumped wafer surface; thermally curing the resist ink; and printing or electroplating solders onto the bumped wafer surface. In some embodiments, the method comprises reflowing the solders to form solder balls. In some embodiments, the method comprises stripping the resist ink. In some embodiments, stripping the resist ink comprises applying an alkaline solution to the bumped wafer surface. In some embodiments, the resist ink is one of: polyimide; solder resist material; polymer material; thermally curable polymer; heat resistant resin; or UV curable polymer. In some embodiments, the method comprises programming an inkjet printer with a pattern of resist ink to be printed.

In another example, a machine readable storage media is provided having one or more instructions that when executed cause a machine to perform an operation according to the method described above.

In another example, an apparatus is provided which comprises: a die with a first side; a plurality of metal bumps on the first side of the die; a printable resist disposed next to at least one of the metal bumps or next to a layer; and a plurality of solders disposed on the plurality of metal bumps. In some embodiments, the layer surrounds the at least one of the metal bumps. In some embodiments, the layer is removal material. In some embodiments, the removal material is a sacrificial resist. In some embodiments, the layer is a permanent material. In some embodiments, the permanent material is a wafer level under-fill. In some embodiments, the layer is deposited on the first side of the die such that it is to provide a flat surface for the printable resist. In some embodiments, the printable resist is an ink injected from an inkjet printer, wherein the ink is at least one of: polyimide; solder resist material; polymer material; thermally curable polymer; heat resistant resin; or Ultraviolet light (UV) curable polymer. In some embodiments, the inkjet printer is operable via software. In some embodiments, the inject printer is operable to inject the printable resist from a single nozzle of the inject printer in a preprogrammed pattern. In some embodiments, the inject printer is operable to inject the printable resist from multiple nozzles of the inject printer. In some embodiments, the die has a second side opposite to the first side, wherein the second side includes one or more transistors.

In another example, a system is provided which comprises: a memory; a processor coupled to the memory; a package encasing the processor, the package including an apparatus according to the apparatus described above; and a wireless interface for allowing the processor to communicate with another device.

In another example, an apparatus is provided which comprises: means for printing a resist ink onto a bumped wafer surface; means for thermally curing the resist ink; and means for printing or electroplating solders onto the bumped wafer surface. In some embodiments, the apparatus comprises means for reflowing the solders to form solder balls. In some embodiments, the apparatus comprises means for stripping the resist ink. In some embodiments, the means for stripping the resist ink comprises means for applying an alkaline solution to the bumped wafer surface. In some embodiments, the resist ink is one of: polyimide; solder resist material; polymer material; thermally curable polymer; heat resistant resin; or UV curable polymer. In some embodiments, the apparatus comprises means for programming an inkjet printer with a pattern of resist ink to be printed.

An abstract is provided that will allow the reader to ascertain the nature and gist of the technical disclosure. The abstract is submitted with the understanding that it will not be used to limit the scope or meaning of the claims. The following claims are hereby incorporated into the detailed description, with each claim standing on its own as a separate embodiment.

1-21. (canceled)

22. An apparatus comprising:
a die with a first side;
a plurality of metal bumps on the first side of the die;
a printable resist disposed next to at least one of the metal bumps on the first side of the die; and
a plurality of solders disposed on the plurality of metal bumps.

23. The apparatus of claim 22, wherein the printable resist is an ink injected from an inkjet printer, wherein the ink is at least one of:
polyimide;
solder resist material;
polymer material;
thermally curable polymer;
heat resistant resin; or
Ultraviolet light (UV) curable polymer.

24. The apparatus of claim 23, wherein the inkjet printer is operable via software.

25. The apparatus of claim 24, wherein the inject printer is operable to inject the printable resist from a single nozzle of the inject printer in a preprogrammed pattern.

26. The apparatus of claim 25, wherein the inject printer is operable to inject the printable resist from multiple nozzles of the inject printer.

27. The apparatus of claim 26, wherein the die has a second side opposite to the first side, and wherein the second side includes one or more transistors.

28. An apparatus comprising:
a die with a first side;
a plurality of metal bumps on the first side of the die; and
a plurality of solders disposed on the plurality of metal bumps, wherein the plurality of metal bumps are positioned according to a patterned printable resist.

29. The apparatus of claim 28, wherein the patterned printable resist is formed using an inkjet printer.

30. The apparatus of claim 29, wherein the patterned printable resist is an ink based resist.

31. The apparatus of claim 30, wherein the inkjet printer is operable to dispose one of:
polyimide ink, solder resist material, polymer material ink, thermally curable polymer ink; or
heat resistant resin ink over next to at least one of the metal bumps of the plurality of metal bumps.

32. The apparatus of claim 29, wherein the inkjet printer is operable via firmware.

33. The apparatus of claim 28, wherein the die has a second side opposite to the first side, and wherein the second side includes one or more transistors.

34. A system comprising:
a memory;
a processor coupled to the memory;
a package encasing the processor, the package including an apparatus which comprises:
a die with a first side;
a plurality of metal bumps on the first side of the die;
a printable resist disposed next to at least one of the metal bumps on the first side of the die; and
a plurality of solders disposed on the plurality of metal bumps; and
a wireless interface to allow the processor to communicate with another device.

35. The system of claim 34, wherein the printable resist is an ink injected from an inkjet printer, wherein the ink is at least one of:
polyimide;
solder resist material;
polymer material;
thermally curable polymer;
heat resistant resin; or
Ultraviolet light (UV) curable polymer.

36. The system of claim 34, wherein the inkjet printer is operable via software.

37. The system of claim 36, wherein the inject printer is operable to inject the printable resist from a single nozzle of the inject printer in a preprogrammed pattern.

38. The system of claim 37, wherein the inject printer is operable to inject the printable resist from multiple nozzles of the inject printer.

39. The system of claim 38, wherein the die has a second side opposite to the first side, and wherein the second side includes one or more transistors.
